(19) United States
(12) Patent Application Publication
(10) Pub. No.: US 2012/0050235 A1
(43) Pub. Date: Mar. 1, 2012

(54) Organic electroluminescence emitting display and method of manufacturing the same

(76) Inventors: Dong-Wook Park, Yongin-City (KR); Chul-Kyu Kang, Yongin-city (KR)

(21) Appl. No.: 13/067,172

(22) Filed: May 13, 2011

(30) Foreign Application Priority Data
Aug. 24, 2010 (KR) 10-2010-0082084

(51) Int. Cl. G06F 3/038; H01L 33/08

(52) U.S. Cl. 345/204; 438/34; 257/E33.012

(57) ABSTRACT

A method of manufacturing the organic light emitting display includes selectively etching an interlayer insulating layer and a gate insulating layer so that a source region and a drain region of a semiconductor layer of a sub pixel unit are exposed and removing the interlayer insulating layer and the gate insulating layer in a data line forming region of a data line unit so that a buffer layer at the data line forming region of the data line unit is exposed, and forming a source electrode and a drain electrode coupled to the exposed semiconductor layer of the sub pixel unit and forming a data line on the exposed buffer layer of the data line forming region of the data line unit.

### BACKGROUND

1. Field

The described embodiments relate to an organic light emitting display and a method of manufacturing the same, and more particularly, to an organic light emitting display capable of preventing RC delay to improve the reliability of the organic light emitting display and to simplify processes and a method of manufacturing the same.

2. Description of the Related Art

Recently, with the development of an information-oriented society, while demand for organic light emitting displays increases, research on displays such as liquid crystal displays (LCD), plasma display panels (PDP), field emission displays (FED), electrophoretic displays (EPD), organic electroluminescence emitting displays (OLED) is being actively performed.

In an organic light emitting display, an organic light emitting diode for generating light by recombination of electrons supplied by a cathode and holes supplied by an anode is used.

### SUMMARY

According to an embodiment, there is provided an organic light emitting display, including a sub pixel defined by a perpendicularly intersecting gate line and data line arranged on a substrate where a buffer layer is disposed, a driving switching element that applies a driving current to the sub pixel, a protective layer disposed on the entire substrate and covering the data line and the driving switching element, and an organic light emitting diode (OLED) disposed on the protective layer in the sub pixel to receive driving current from the driving switching element, wherein the data line is disposed on the buffer layer through an interlayer insulating layer and a gate insulating layer.

The data line may include a same material as a source electrode and a drain electrode of the driving switching element.

The data line may be buried in the interlayer insulating layer and the gate insulating layer.

The data line may be planarized .with the interlayer insulating layer.

The organic light emitting display may further include a planarizing layer on the protective layer that covers the data line and the driving switching element. A thickness of the planarizing layer on the data line may be greater than a thickness of the planarizing layer on the driving switching element.

According to an embodiment, a method of manufacturing an organic light emitting display includes forming a buffer layer on an entire substrate defined by a sub pixel unit and a data line unit, forming a semiconductor layer on the buffer layer of the sub pixel unit, forming a gate insulating layer on an entire surface of the substrate the semiconductor layer is disposed, forming a gate electrode on the gate insulating layer of the sub pixel unit, overlapping the semiconductor layer, forming an interlayer insulating layer on the entire surface of the substrate, covering the gate electrode, selectively etching the interlayer insulating layer and the gate insulating layer such that a source region and a drain region of the semiconductor layer of the sub pixel unit are exposed and at least partially removing the interlayer insulating layer and the gate insulating layer of the data line unit so that the buffer layer of the data line unit is exposed, and forming a source electrode and a drain electrode coupled to the exposed semiconductor layer of the sub pixel unit and forming a data line on the exposed buffer layer of the data line unit.

The data line may be buried in the interlayer insulating layer and the gate insulating layer.

The data line may be planarized with the interlayer insulating layer.

The method may further include forming a protective layer on an entire surface of the substrate where the data line, the source electrode, and the drain electrode are disposed, forming an anode electrically coupled to the drain electrode through the protective layer in the sub pixel unit, forming a planarizing layer on the substrate such that the anode is exposed, forming an organic light emitting layer on the exposed anode, and forming a cathode on the entire surface of the substrate where the organic light emitting layer is formed to form an OLED.

A thickness of the planarizing layer formed on the data line may be greater than a thickness of the planarizing layer formed on the source electrode and the drain electrode.

According to an embodiment, a method of manufacturing an organic light emitting display includes forming a buffer layer on an entire substrate defined by a sub pixel unit and a data line unit, forming a driving switching element on the buffer layer at the sub pixel unit, forming a data line on the buffer layer at the data line unit, forming a protective layer on the entire surface of the substrate where the driving switching element and the data line are exposed, and forming an OLED electrically coupled to the driving switching element on the protective layer of the sub pixel unit, wherein the forming of the data line on the buffer layer at the data line unit includes at least partially exposing the data line unit simultaneously with performing a contact hole process to form a source electrode and a drain electrode of the driving switching element.

The data line may be buried in an interlayer insulating layer and a gate insulating layer formed on the entire surface of the substrate.

The data line may be planarized with the interlayer insulating layer.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1A illustrates a view for simplifying the layout of the organic light emitting display according to an embodiment;

FIG. 1B illustrates a sectional view relating to the organic light emitting display according to FIG. 1A taken along the line A-A′;

FIG. 1C illustrates a sectional view relating to the organic light emitting display according to FIG. 1A taken along the line B-B′; and

FIGS. 2A to 2I illustrate sectional views relating to a method of manufacturing the organic light emitting display according to FIG. 1A.

### DETAILED DESCRIPTION

Korean Patent Application No. 10-2010-0082084, filed on Aug. 24, 2010, in the Korean Intellectual Property Office, and entitled: “Organic Electroluminescence Emitting Display Device and Manufacturing Method of the Same” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate or surface of a substrate, such a layer or element may be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Hereinafter, an organic light emitting display according to an embodiment and a method of manufacturing the same will be described in detail with reference to the accompanying drawings.

Here, i) shapes, sizes, ratios, angles, and numbers that are illustrated in the accompanying drawings may be slightly changed. ii) Since the drawings are depicted from observer's eyes, the directions and positions illustrating the drawings may be variously changed according to the observer's position. iii) Although different reference numerals may be assigned to the same part.

iv) In the case where the terms ‘comprising’, ‘having’, and ‘including’ are used, another term may be added when the term ‘only’ is not used. v) A singularity may be interpreted by plurality. vi) Although shapes, comparison of size, and positional relationship are not explained by ‘about’, ‘substantially’, etc., the shapes, comparison of size, and positional relationship are interpreted to include usual error range.

vii) Although the terms ‘after˜’, ‘before ˜’, ‘then’, ‘and’, ‘here’, ‘next’, ‘at this time’, and ‘in this case’ are used, the terms do not mean the limitation of time position. viii) The terms ‘first’, ‘second’, and ‘third’, etc. are used for conventional distinguish selectively, exchangeably, or repeatedly, but are not interpreted by limit meaning.

ix) In the case where positional relationship between two parts such as ‘on ˜’, ‘above ˜’, ‘under ˜’, and ‘beside ˜’ is described, one or more other part may be positioned between the two parts when the term ‘directly’ is not used. x) When parts are described using the term ‘or’ as a connector, the term ‘or’ as a connector may be interpreted to refer not only to the described parts singly but also to combinations of the parts. When the parts are described using the term ‘one of˜, or ˜’, such a phrase may refer to the described parts in the alternative.

Organic Electroluminescence Emitting Display

The organic light emitting display according to the described embodiment includes a plurality of sub pixels. However, hereinafter, the organic light emitting display according to an embodiment will be described with reference to one sub pixel. The aspects described herein may be applied to the other sub pixels formed in the organic light emitting display.

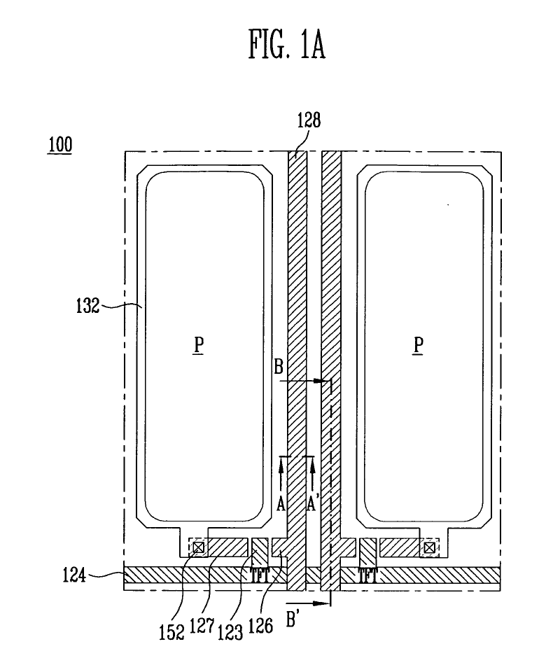

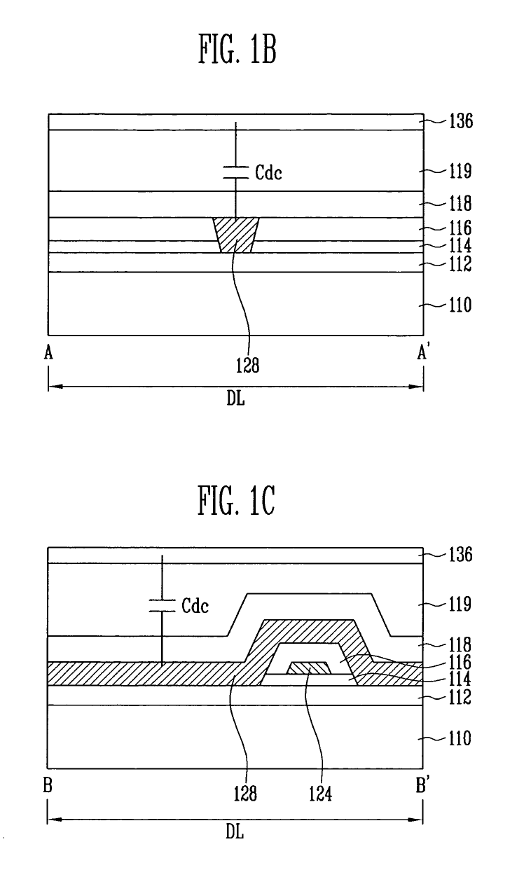

Referring to FIGS. 1A to 1C, the organic light emitting display according to an embodiment includes a gate line 124 and a data line 128 perpendicularly arranged on a substrate 110, an organic light emitting diode (OLED) formed in the sub pixel unit P defined by perpendicularly intersecting the gate line 124 and the data line 128, and a driving switching element TFT for supplying driving current to the OLED. The substrate 110 may be defined as the sub pixel unit P and a data line unit DL. Herein, where it is described or recited herein that a layer is formed “on the entire substrate” or “on an entire surface of the substrate,” such description or recitation refers to the substrate in the region of the sub pixel unit P and the data line unit DL and does not require that the layer be formed over the entire organic light emitting display device.

The OLED formed in the sub pixel unit P emits red, green, and blue light components in accordance with the flow of driving current supplied through a driving switching element TFT to display predetermined image information. The OLED includes an anode 132 electrically coupled to the driving switching element TFT, a cathode 136 electrically coupled to a power source wiring line (not shown), and an organic light emitting layer (not shown) provided between the anode 132 and the cathode 136.

The anode 132 is formed on a planarizing layer 118 to be electrically coupled to a drain electrode 127 of the driving switching element TFT through a first contact hole 152. The anode 132 may be formed of a transparent conductive material in the sub pixel unit P. The transparent conductive material may be formed of an indium tin oxide (ITO), a tin oxide (TO), indium zinc oxide (IZO), indium tin zinc oxide (ITZO), or a combination of the above materials.

The organic light emitting layer (not shown) is a layer, in which holes and electrons injected from the anode 132 and the cathode 136 are coupled to each other to form exiton that falls down to a base state and to emit a layer. The organic light emitting layer (not shown) includes a hole injection layer (HIL), a hole transporting layer (HTL), an emission layer (EL), an electron transporting layer (ETL), and an electron injection layer (EIL).

The plate-shaped cathode 136 is entirely formed on the substrate 110. The cathode 136 may be formed of a non-transparent conductive material or a transparent conductive material. Cr, Al, AlNd, Mo, Cu; W, Au, Ni, Ag, an alloy of the above, or an oxide is used as the non-transparent conductive material or a lamination structure of the above may be used. The OLED formed as described above emits red, green, and blue light components in units of sub pixels in accordance with the driving current of the driving switching element TFT to display an image.

The driving switching element TFT is formed in a region where the gate line 124 and the data line 128 perpendicularly intersects to supply driving current to the OLED formed in the sub pixel unit P. Therefore, the driving switching element TFT is electrically coupled to the anode 132 to apply current to the OLED.

The driving switching element TFT includes a semiconductor layer 121 formed on a buffer layer 112 of the substrate 110 and a gate electrode 123 formed to overlap the channel of the semiconductor layer 121. The driving switching element TFT further includes a source electrode 126 and the drain electrode 127 that contact the source region and the drain region in the semiconductor layer 121 on both sides of the gate electrode 123 through an interlayer insulating layer 116 and the gate insulating layer 114.

The term “data line unit DL” may refer to an area in which the data line 128 for supplying the data signal to a driving switching element TFT in response to the scan signal of the gate line 124 is formed. The data line unit DL may be defined as a region between one side of each of the long sides of the adjacent sub pixel units P. The term “data line forming region” may refer to the specific location in the data line unit DL where the data line 128 is formed.

The buffer layer 112, the data line 128, the protective layer 118, the planarizing layer 119, and the cathode 136 are sequentially laminated on the substrate 110 of the data line unit DL. According to an embodiment, the data line 128 is formed on the buffer layer 112 on the substrate 110 through the gate insulating layer 114 and the interlayer insulating layer 116. For example, the data line 128 may be disposed directly on the buffer layer 112, except for where the data line 128 intersects the gate line 124.

The data line 128 may be buried in the gate insulating layer 114 and the interlayer insulating layer 116. Accordingly, the data line 128 may not form step difference and may be planarized with the interlayer insulating layer 116 on the gate insulating layer 114. The thicknesses of the protective layer 118 and the planarizing layer 119 sequentially laminated on the data line 128 by the data line 128 planarized with the interlayer insulating layer 116 may be larger than the thicknesses of the protective layer 118 and the planarizing layer 119 sequentially laminated on the gate line 124.

The data line 128 may be formed of the same material as the source electrode 126 and the drain electrode 127 of the driving switching element TFT. Since the data line 128 may be formed in the interlayer insulating layer 116 and the gate insulating layer 114, the thicknesses of the protective layer 118 and the planarizing layer 119 on the data line 128 are larger than the thicknesses of the protective layer 118 and the planarizing layer 119 on the source electrode 126 and the drain electrode 127 of the driving switching element TFT.

If the data line 128 according to an embodiment does not form step difference on an insulating layer, the data line 128 does not affect the thickness of the insulating layer such as the protective layer 118 or/and the planarizing layer 119 formed on the data line 128. According to an embodiment, if the thickness of the protective layer 118 or/and the planarizing layer 119 on the data line 128 is increased by removing the gate insulating layer 114 and the interlayer insulating layer 116 under the data line 128, the distance between the data line 128 and the cathode 136 is increased.

As a result, the parasitic capacitance Cdc generated between the data line 128 and the cathode 136 may be reduced. Accordingly, the RC delay of the data line 128 may be prevented. As a result of experiment, the parasitic capacitance Cdc of about 9% to 36% may be reduced. As described above, according to an embodiment, the RC delay of the data line 128 may be prevented. Accordingly, the driving of the organic light emitting display may be stabilized so that the reliability of the organic light emitting display may be improved.

The elements denoted by the same reference numeral of the sub pixel unit P and the data line unit DL may be formed of the same material.

Method of Manufacturing Organic Electroluminescence Emitting Display

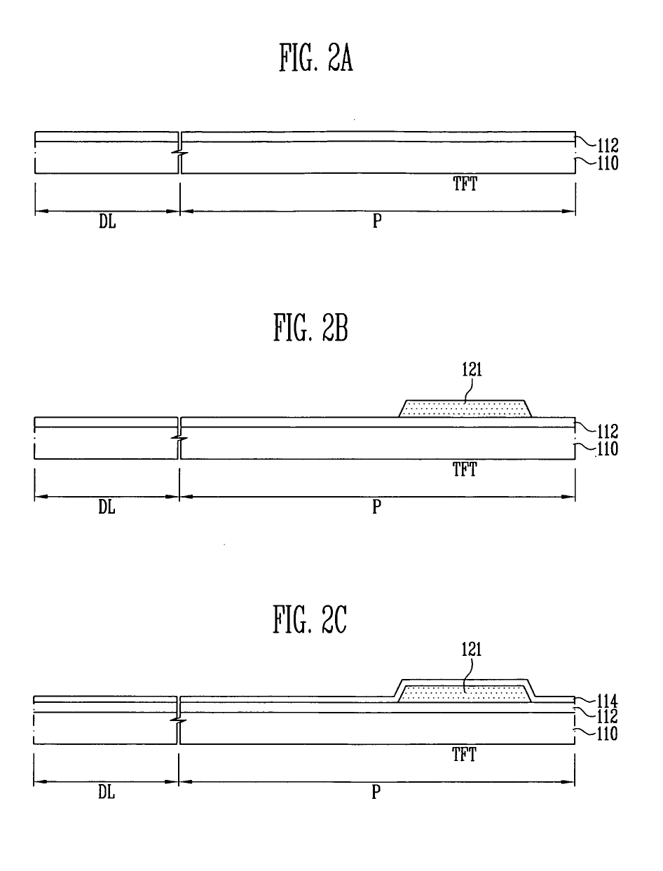

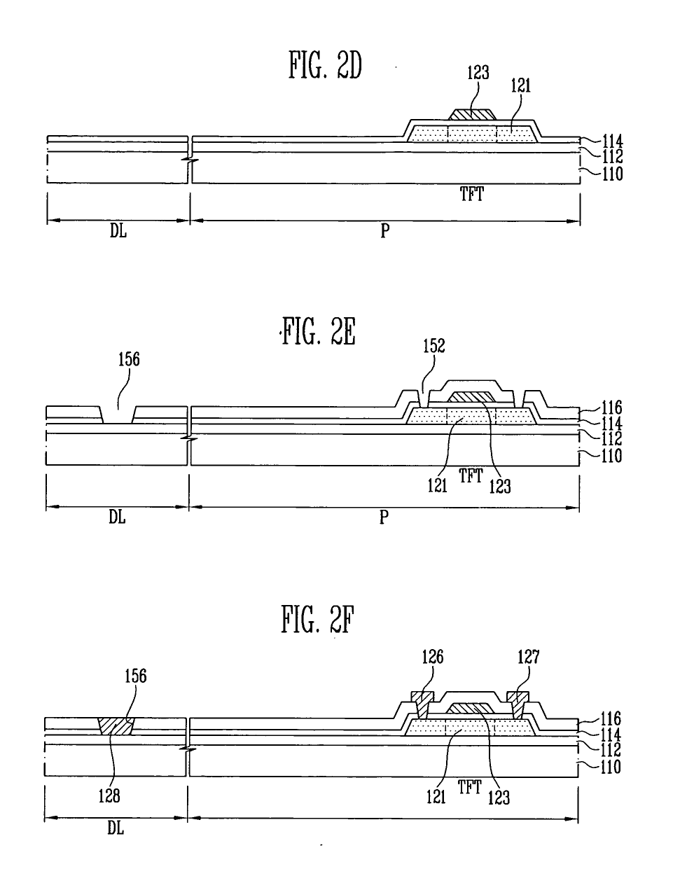

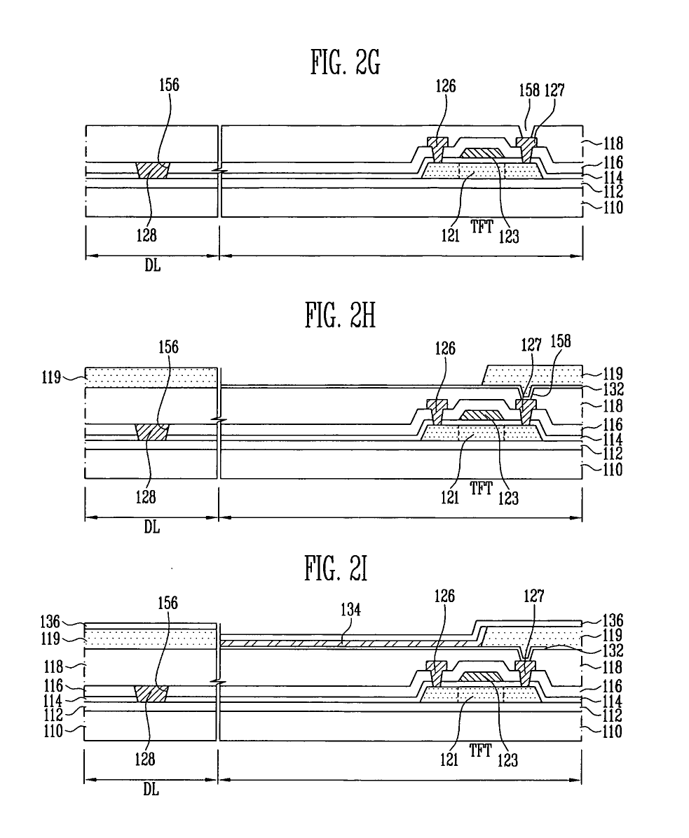

Hereinafter, a method of manufacturing the organic electroluminescence emitting display illustrated in FIG. 1A will be described with reference to FIGS. 2A to 2I.

Referring to FIG. 2A, in the method of manufacturing the organic light emitting display according to an embodiment, after preparing a substrate 110 defined by the sub pixel unit P and the data line unit DL, the buffer layer 112 is entirely formed on the substrate 110.

Referring to FIG. 2B, after forming an amorphous silicon layer or a polycrystalline silicon layer on the entire surface of the substrate 110, the amorphous silicon layer or the polycrystalline silicon layer are patterned in the form of an island by the photolithography process and the etching process to form a semiconductor layer 121 on the substrate 110 of the sub pixel unit P.

Referring to FIG. 2C, a gate insulating layer 114 is formed on the entire surface of the substrate 110 including the semiconductor layer 121. The gate insulating layer 114 may be formed of a single layer of an inorganic insulating material such as a silicon nitride layer SiNₓ and a silicon oxide layer SiOₓ or a multiple layer of the silicon nitride layer SiNₓ and the silicon oxide layer SiOₓ.

Referring to FIG. 2D, after depositing a first non-transparent conductive material, the first non-transparent conductive material is patterned by the photolithography process and the etching process so that the gate electrode 123 is formed on the gate insulating layer 114 to overlap the semiconductor layer 121 of the sub pixel unit P. At this time, the gate line (not shown) is formed together.

A single layer of Mo, W, Ti, Cu, Al, Nd, and Cr, a single layer of an alloy of the above materials, a multiple layer structure of the above materials, or a multiple layer structure of the alloy of the above materials may be used as the first non-transparent conductive material.

Referring to FIG. 2E, impurity ions are injected into the semiconductor layer 121 using the gate electrode 123 as a mask to form a source region and a drain region. Then, after forming the interlayer insulating layer 116 on the entire surface of the substrate 110 where the gate electrode 123 is formed, the interlayer insulating layer 116 and the gate insulating layer 114 are selectively etched in order to form the first contact hole 152 that exposes the source region and the drain region of the semiconductor layer 121.

At this time, the interlayer insulating layer 116 and the gate insulating layer 114 of the data line unit DL are simultaneously etched so that a second contact hole 156 that exposes the buffer layer 112 is formed.

Referring to FIG. 2F, a second non-transparent conductive material is formed on the substrate 110 so that the first contact hole 152 and the second contact hole 156 are buried and the second non-transparent conductive material is patterned by the photolithography process and the etching process to form the source electrode 126 and the drain electrode 127 coupled to the source region and the drain region of the semiconductor layer 121 through the interlayer insulating layer 116 and the gate insulting layer 114 of the sub pixel unit P.

Simultaneously, the data line 128 is formed on the buffer layer 112 exposed through the interlayer insulating layer 116 and the gate insulating layer 114 of the data line unit DL. Therefore, the driving switching element TFT is completed in the sub pixel unit P and the data line 128 is completed in the data line unit DL. The data line 128 of the data line unit DL is planarized with the top surface of the interlayer insulating layer 116.

A single layer of Mo, W, Ti, Cu, Al, Nd, and Cr, a single layer of an alloy of the above materials, a multiple layer structure of the above materials, or a multiple layer structure of the alloy of the above materials may be used as the first non-transparent conductive material.

Referring to FIG. 2G, the protective layer 118 having a contact hole 158 that exposes the drain electrode 127 of the driving switching element TFT is formed on the entire surface of the substrate 110. The protective layer 118 may be formed of a single layer of a silicon oxide layer SiO₂ or a silicon nitride layer SiNₓ or a plurality of layers of the silicon oxide layer SiO₂ or the silicon nitride layer SiNₓ. At this time, since the data line 128 does not have step difference, the protective layer 118 on the data line 128 may be formed to be flat without having step difference.

Referring to FIG. 2H, after depositing the transparent conductive material, the transparent conductive material is patterned by the photolithography process and the etching process using the mask to form the anode 132 coupled to the drain electrode 127 exposed by the contact hole 158 on the protective layer 118 of the sub pixel unit P.

Indium tin oxide (ITO), tin oxide (TO), indium zinc oxide (IZO), indium tin zinc oxide (ITZO), or a combination of the above materials may be used.

Then, after coating the entire surface of the substrate 110 where the anode 132 is formed with the planarizing layer 119, the planarizing layer 119 is selectively removed so that the anode 132 of the sub pixel unit P is exposed to separate the OLED in units of sub pixels. At this time, since the data line 128 and the protective layer 118 of the data line unit DL do not have step difference, the planarizing layer 119 does not have step difference and is formed to be flat.

Referring to FIG. 2I, an organic light emitting layer 134 laminated by organic materials is formed on the exposed anode 132 of the sub pixel unit P through a deposition method such as thermal deposition. The organic light emitting layer 134 includes a hole injection layer (HIL), a hole transporting layer (HTL), an emission layer (EL), an electron transporting layer (ETL), and an electron injection layer (EIL).

At this time, the emission layer is formed on the anode 132 to be separated in units of sub pixels to emit red, green, and blue light components in units of sub pixels. Then, a conductive material is deposited on the entire surface of the substrate 110 where the organic light emitting layer 134 is formed to form the cathode 136 to manufacture the organic light emitting display.

As described above, since the data line 128 manufactured according to an embodiment does not form a step difference on an insulating layer, the data line 128 does not affect the thickness of an insulating layer such as the protective layer 118 or/and the planarizing layer 119 formed on the data line 128. That is, according to an embodiment, since the thickness of the protective layer 118 or/and the planarizing layer 119 on the data line 128 increases by removing the gate insulating layer 114 and the interlayer insulating layer 116 under the data line 128, the distance between the data line 128 and the cathode 136 increases.

As a result, the parasitic capacitance Cdc generated between the data line 128 and the cathode 136 is reduced. Accordingly, the RC delay of the data line 128 may be prevented. According to an embodiment, the RC delay of the data line 128 may be prevented. Accordingly, the driving of the organic light emitting display is stabilized and the reliability of the organic light emitting display may be improved.

Furthermore, the contact hole for the data line 128 may be formed together in a contact hole process of forming the source electrode and the drain electrode that constitute the driving switching element TFT of the sub pixel unit P. Accordingly, an additional mask and an additional process may not be required. According to an embodiment, the RC delay of the data line 128 may be improved while simplifying processes.

By way of summation and review, an organic light emitting display includes organic light emitting diodes (OLED) formed in sub pixels defined by gate wiring lines and data wiring lines that perpendicularly intersect with each other to display an image and driving switching elements electrically coupled to the OLEDs to supply driving current.

In general, since the data wiring lines may be formed in processes of forming the source/drain electrodes of the driving switching elements, various insulating layers such as a gate insulating layer and an interlayer insulating layer may exist under the data wiring line. Step differences may be formed in the data wiring line due to flat insulating layers that exist under the data wiring lines.

The step difference of the data wiring line may affect the insulating layer formed on the wiring line. At this time, a parasitic capacitance may be formed between the data wiring line and a cathode formed on the data wiring line with an insulating layer interposed. Such parasitic capacitance may cause the RC delay of the data wiring line.

In particular, a planarizing layer that is an insulating layer formed on the data wiring line may be relatively thin in comparison with the place where the step difference of the data wiring line does not exist due to the step difference of the data wiring line. The parasitic capacitance between the data wiring line and the cathode may increase in inverse proportion to the thickness of the thinly formed planarizing layer.

In accordance with the increasing parasitic capacitance, the RC delay of the data wiring line may deteriorate so that it may be difficult to drive the organic light emitting display so that the reliability of the organic light emitting display deteriorates.

Accordingly, the described embodiments been made to provide an organic light emitting display capable of preventing RC delay to improve the reliability of the organic light emitting display and to simplify processes and a method of manufacturing the same. According to an embodiment, the data line is formed to be buried in the interlayer insulating layer and the gate insulating layer so that parasitic capacitance generated between the data line and the cathode is reduced and that the RC delay of the data lines may be prevented.

According to an embodiment, since the RC delay of the data line may be prevented, the driving of the organic light emitting display is stabilized and the reliability of the organic light emitting display may be improved.

Furthermore, according to an embodiment, since contact holes for forming the data lines are formed in a contact hole process of forming the source electrode and the drain electrode that constitute the driving switching, element, an additional mask and an additional process are not required so that processes may be simplified.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting display, comprising:
a sub pixel defined by a perpendicularly intersecting gate line and data line arranged on a substrate where a buffer layer is disposed;
a driving switching element that applies a driving current to the sub pixel;
a protective layer disposed on the entire substrate covering the data line and the driving switching element; and
an organic light emitting diode (OLED) disposed on the protective layer in the sub pixel to receive driving current from the driving switching element,
wherein the data line is disposed on the buffer layer through an interlayer insulating layer and a gate insulating layer.

2. The organic light emitting display as claimed in claim 1, wherein the data line includes a same material as a source electrode and a drain electrode of the driving switching element.

3. The organic light emitting display as claimed in claim 1, wherein the data line is buried in the interlayer insulating layer and the gate insulating layer.

4. The organic light emitting display as claimed in claim 1, wherein the data line is planarized with the interlayer insulating layer.

5. The organic light emitting display as claimed in claim I, further comprising a planarizing layer on the protective layer that covers the data line and the driving switching element,
wherein a thickness of the planarizing layer on the data line is greater than a thickness of the planarizing layer on the driving switching element.

6. A method of manufacturing an organic light emitting display, comprising:
forming a buffer layer on an entire substrate defined by a sub pixel unit and a data line unit;
forming a semiconductor layer on the buffer layer of the sub pixel unit;
forming a gate insulating layer on the entire surface of the substrate where the semiconductor layer is disposed;
forming a gate electrode on the gate insulating layer of the sub pixel unit, overlapping the semiconductor layer;
forming an interlayer insulating layer on the entire surface of the substrate, covering the gate electrode;
selectively etching the interlayer insulating layer and the gate insulating layer such that a source region and a drain region of the semiconductor layer of the sub pixel unit are exposed and at least partially removing the interlayer insulating layer and the gate insulating layer of the data line unit so that the buffer layer of the data line unit is exposed; and
forming a source electrode and a drain electrode coupled to the exposed semiconductor layer of the sub pixel unit and forming a data line on the exposed buffer layer of the data line unit.

7. The method as claimed in claim 6, wherein the data line is buried in the interlayer insulating layer and the gate insulating layer.

8. The method as claimed in claim 6, wherein the data line is planarized with the interlayer insulating layer.

9. The method as claimed in claim 6, further comprising:
forming a protective layer on an entire surface of the substrate where the data line, the source electrode, and the drain electrode are disposed;
forming an anode electrically coupled to the drain electrode through the protective layer in the sub pixel unit;
forming a planarizing layer on the substrate such that the anode is exposed;
forming an organic light emitting layer on the exposed anode; and
forming a cathode on the entire surface of the substrate where the organic light emitting layer is formed to form an OLED.

10. The method as claimed in claim 9, wherein a thickness of the planarizing layer formed on the data line is greater than a thickness of the planarizing layer formed on the source electrode and the drain electrode.

11. A method of manufacturing an organic light emitting display, comprising:
forming a buffer layer on an entire substrate defined by a sub pixel unit and a data line unit;
forming a driving switching element on the buffer layer at the sub pixel unit;
forming a data line on the buffer layer at the data line unit;
forming a protective layer on the entire surface of the substrate where the driving switching element and the data line are disposed; and
forming an OLED electrically coupled to the driving switching element on the protective layer of the sub pixel unit,
wherein the forming of the data line on the buffer layer includes at least partially exposing the data line unit simultaneously with performing a contact hole process to form a source electrode and a drain electrode of the driving switching element.

12. The method as claimed in claim 11, wherein the data line is buried in an interlayer insulating layer and a gate insulating layer formed on the entire surface of the substrate.

13. The method as claimed in claim 12, wherein the data line is planarized with the interlayer insulating layer.
